(19) United States
(12) Patent Application Publication
(10) Pub. No.: US 2024/0055491 A1
(43) Pub. Date: Feb. 15, 2024

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Chia-Hung Chu, Taipei City (TW); Shuen-Shin Liang, Hsinchu County (TW); Chung-Liang Cheng, Changhua County (TW); Sung-Li Wang, Hsinchu County (TW); Chien Chang, Hsinchu (TW); Harry CHIEN, Chandler, AZ (US); Lin-Yu Huang, Hsinchu (TW); Min-Hsuan Lu, Hsinchu City (TW)

(73) Assignee: Taiwan Semiconductor Manufacturing Company, Ltd., Hsinchu (TW)

(21) Appl. No.: 17/885,577

(22) Filed: Aug. 11, 2022

(51) Int. Cl. H01L 29/417; H01L 29/45; H01L 29/40; H01L 29/66

(52) U.S. Cl. CPC H01L 29/41733; H01L 29/458; H01L 29/401; H01L 29/66439; H01L 29/66742; H01L 29/775

(57) ABSTRACT

A semiconductor device includes parallel channel members, a gate structure, source/drain features, a silicide layer, and a source/drain contact. The parallel channel members are spaced apart from one another. The gate structure is wrapping around the channel members. The source/drain features are disposed besides the channel members and at opposite sides of the gate structure. The silicide layer is disposed on and in direct contact with the source/drain features. The source/drain contact is disposed on the silicide layer, wherein the source/drain contact includes a first source/drain contact and a second source/drain contact stacked on the first source/drain contact, and the second source/drain contact is separate from the silicide layer by the first source/drain contact.

### BACKGROUND

The semiconductor integrated circuit (IC) industry has experienced exponential growth. Technological advances in IC materials and design have produced generations of ICs where each generation has smaller and more complex circuits than the previous generation, therefore, semiconductor structures need to be improved.

### BRIEF DESCRIPTION OF THE DRAWINGS

FIGS. 1-12, FIG. 13A, FIG. 14A and FIG. 15A illustrate schematic cross-sectional views of a semiconductor device during various stages of a fabrication process according to some embodiments of the present disclosure.

FIG. 13B, FIG. 13C and FIG. 13D are schematic enlarged views of a portion of the exemplary structure of the semiconductor device according to some embodiments of the present disclosure.

FIG. 14B is a schematic enlarged view of a portion of the exemplary structure of the semiconductor device according to some embodiments of the present disclosure.

FIG. 14C and FIG. 14D are schematic cross-sectional views of a portion of the exemplary structure of the semiconductor device according to some embodiments of the present disclosure.

FIG. 15B, FIG. 15C and FIG. 15D are schematic enlarged views of a portion of the exemplary structure of the semiconductor device according to some embodiments of the present disclosure.

FIGS. 16-22 illustrate schematic cross-sectional views of a semiconductor device during a fabrication process, according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

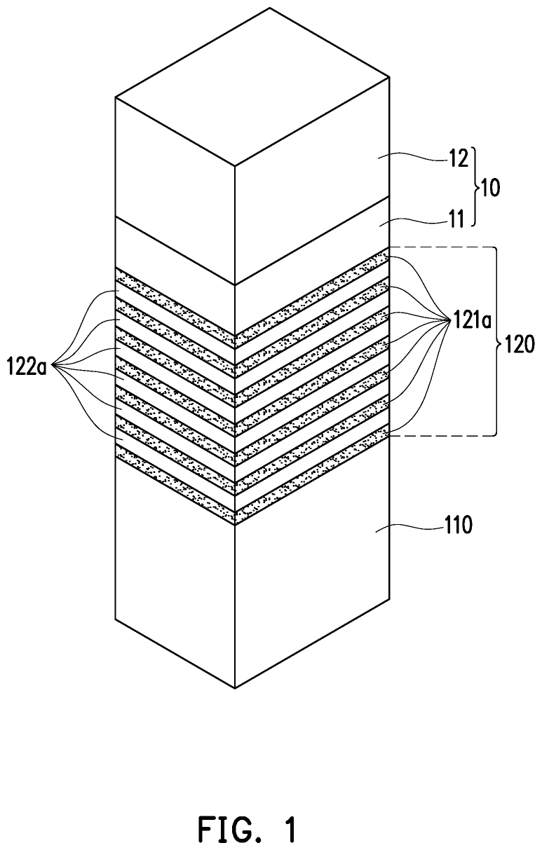

FIGS. 1-12, FIG. 13A, FIG. 14A and FIG. 15 illustrate schematic cross-sectional views of a semiconductor device during various stages of a fabrication process according to some embodiments of the present disclosure. Referring to FIG. 1, a substrate 110 is provided. In some embodiments, the substrate 110 is a semiconductor substrate such as a silicon substrate. The substrate 110 may include various layers, including conductive or insulating layers formed on a semiconductor substrate. Further, the substrate 110 may include various doping configurations depending on design requirements. In some embodiments, different doping profiles (e.g., n-wells, p-wells) are formed on the substrate 110 in regions designed for different device types (e.g., n-type devices and p-type devices). The suitable doping may include ion implantation of dopants and/or diffusion processes. In some embodiments, the substrate 110 also includes other semiconductors such as germanium, silicon carbide (SiC), silicon germanium (SiGe), or diamond. Alternatively, the substrate 110 may include a compound semiconductor, an alloy semiconductor, an epitaxial layer (epi-layer), a silicon-on-insulator (SOI) structure, and/or may have other suitable enhancement features.

A stack 120 of alternating semiconductor layers is formed on substrate 110. In some embodiments, the stack 120 includes epitaxial layers 121a interposed by epitaxial layers 122a. In some embodiments, the epitaxial layers 121a include silicon germanium (SiGe) and the epitaxial layers 122a include silicon (Si). It should be noted that a number of aforementioned layers which is for illustrative purposes only and not intended to be limiting beyond what is specifically recited in the claims. It can be appreciated that any number of epitaxial layers can be formed in the stack 120. The number of layers depends on the desired number of channels members for the semiconductor device 100.

In some embodiments, the epitaxial layers 121a have a substantially uniform first thickness and the epitaxial layers 122a have a substantially uniform second thickness. The first thickness and the second thickness may be identical or different. As described in more detail below, the epitaxial layers 122a or parts thereof may serve as channel member(s) for a subsequently-formed multi-gate device and the thickness of each of the epitaxial layers 122a may be chosen based on device performance considerations. The epitaxial layers 121a may eventually be removed and serve to define a vertical distance for a subsequently-formed multi-gate device and the thickness of each of the epitaxial layers 121a may be chosen based on device performance considerations.

In some embodiments, epitaxial growth of the layers in the stack 120 is performed by a molecular beam epitaxy (MBE) process, a metalorganic chemical vapor deposition (MOCVD) process, and/or other suitable epitaxial growth processes. In some embodiments, the epitaxially grown layers such as, the epitaxial layers 122a include the same material as the substrate 110. In some embodiments, the epitaxial layers 121a include an epitaxially grown silicon germanium (SiGe) layer and the epitaxial layers 122a include an epitaxially grown silicon (Si) layer. Alternatively, in some embodiments, either of the epitaxial layers 121a and the epitaxial layers 122a include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof.

A hard mask layer 10 is formed on the substrate 110, wherein the hard mask layer 10 may be a single layer or a multi-layer. In some embodiments, the hard mask layer 10 includes a first hard mask layer 11 and a second hard mask layer 12 on the first hard mask layer 11. In some implementations, the first hard mask layer 11 is formed of silicon oxide and the second hard mask layer 12 is formed of silicon nitride. The hard mask layer 10 may be formed using chemical vapor deposition (CVD), low-pressure CVD (LPCVD), plasma-enhanced CVD (PECVD), physical vapor deposition (PVD), atomic layer deposition (ALD), thermal oxidation, electron-beam (e-beam) evaporation, or other suitable deposition techniques, or combinations thereof.

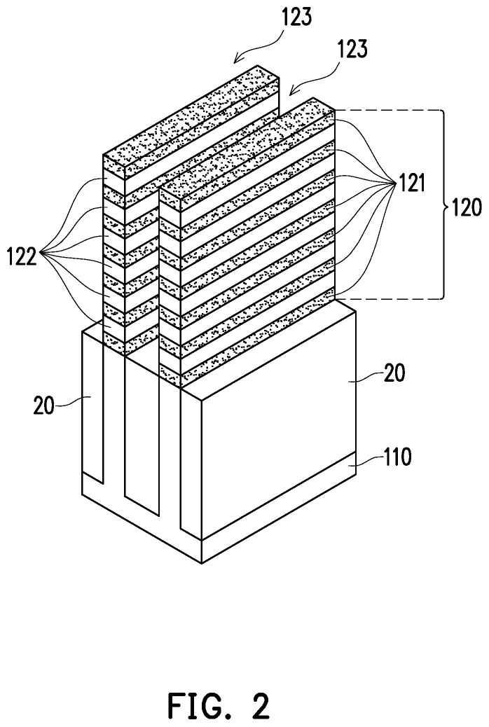

Referring to FIG. 2, the stack 120 is patterned to form patterned epitaxial layers 121a, patterned epitaxial layers 122a, and trenches 123 by using a lithography process and an etch process. The patterned epitaxial layers 121a refer to as sacrificial layers 121, and the patterned epitaxial layers 122a refer to as channel layers 122 as below. In some embodiments, the lithography process includes photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process includes dry etching (e.g., RIE etching), wet etching, and/or other etching methods.

The isolation features 20 are formed in the trenches 123. The isolation features 20 may also be referred to as a shallow trench isolation (STI). In some embodiments, a dielectric layer is first deposited on the substrate 110, filling the trenches 123 with the dielectric material. In some embodiments, the dielectric layer includes silicon oxide, silicon nitride, silicon oxynitride, fluorine-doped silicate glass (FSG), a low-k dielectric, combinations thereof, and/or other suitable materials. In various examples, the dielectric layer is deposited by a CVD process, a sub-atmospheric CVD (SACVD) process, a flowable CVD process, an ALD process, a physical vapor deposition (PVD) process, and/or other suitable process. The deposited dielectric material is then thinned and planarized, for example by a chemical mechanical polishing (CMP) process. The planarized dielectric layer is further recessed or pulled-back by a dry etching process, a wet etching process, and/or a combination thereof to form the isolation features 20. In some embodiments, the substrate 110 have the isolation features 20 interposing the regions providing different device types.

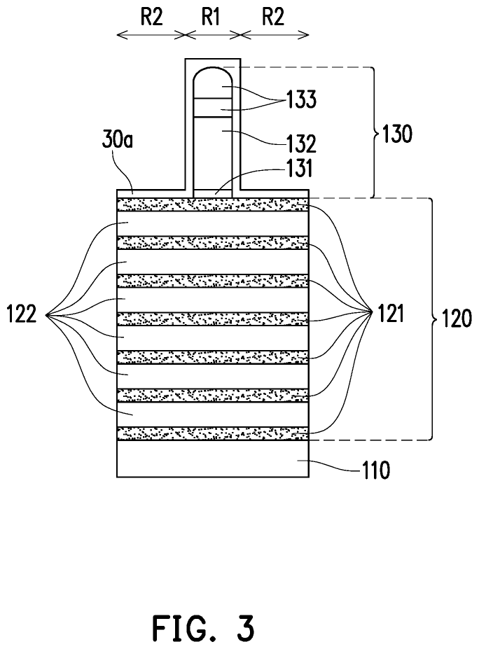

Referring to FIG. 3, a dummy gate stack 130 is formed on the substrate 110. In some embodiments, the substrate 110 has first regions R1 and second regions R2, the first regions R1 refers to the region where channel regions or channel sheets are formed, which is located mainly below the dummy gate stack 130, while the second regions R2 refers to the regions where the source and drains are to be formed. As shown in FIG. 3, the first region R1 is disposed between the second regions R2. In some embodiments, a gate replacement process (or gate-last process) is adopted where the dummy gate stack 130 serves as a placeholder to undergo various processes and is to be removed and replaced by the functional gate structure. Other processes and configuration are possible.

In the illustrated embodiment, a dummy gate stack 130 includes a dummy gate dielectric layer 131. In some embodiments, the dummy gate dielectric layer 131 includes silicon oxide, silicon nitride, a high-K dielectric material and/or other suitable material. In various examples, the dummy gate dielectric layer 131 is deposited by a CVD process, a sub-atmospheric CVD (SACVD) process, a flowable CVD process, an ALD process, a PVD process, or other suitable process. Subsequently, other portions of the dummy gate stack 130, including a dummy gate electrode 132 and a gate top hard mask 133. In some embodiments, the dummy gate stack 130 is formed by various process steps such as layer deposition, patterning, etching, as well as other suitable processing steps. Exemplary layer deposition processes include low-pressure CVD, CVD, plasma-enhanced CVD (PECVD), PVD, ALD, thermal oxidation, e-beam evaporation, or other suitable deposition techniques, or combinations thereof. For example, the patterning process includes a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process includes dry etching (e.g., RIE etching), wet etching, and/or other etching methods. In some embodiments, the dummy gate electrode 132 includes polycrystalline silicon (polysilicon). In some embodiments, the gate top hard mask 133 includes an oxide layer such as a pad oxide layer that may include silicon oxide, as well as a nitride layer such as a pad nitride layer that may include silicon nitride, silicon oxynitride and/or silicon carbide.

A gate material layer 30a is formed on the substrate 110. In some embodiments, spacer material for forming the gate spacer layer 30a is deposited conformally over the substrate 110, including over top surfaces and sidewalls of the dummy gate stack 130 to form a gate material layer 30a. The term “conformally” may be used herein for ease of description of a layer having substantially uniform thickness over various regions. The gate material layer 30 may have a single-layer construction or include multiple layers. In some embodiments, the gate material layer 30 may include silicon carbonitride, silicon oxycarbide, silicon oxycarbonitride, or silicon nitride. The spacer material layer may be deposited over the dummy gate stack 130 using processes such as, CVD process, a sub-atmospheric CVD (SACVD) process, a flowable CVD process, an ALD process, a PVD process, or other suitable process.

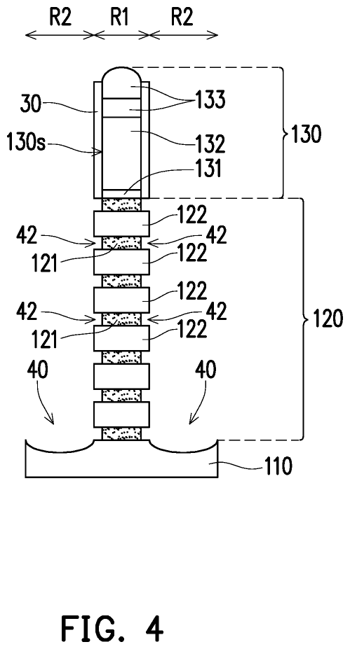

Referring to FIG. 4, the gate material layer 30a may then be etched back in an anisotropic etch process to formed gate spacer layer 30. In some embodiments, portions of the gate material layer 30a directly over the dummy gate stack 130 may be completely removed by this anisotropic etch process while the gate material layer 30a remains on sidewalls 130s of the dummy gate stack 130 to form gate spacer layer 30. Subsequently, the second regions R2 may be recessed to form a source/drain recesses 40. While not explicitly shown, a photolithography process and at least one hard mask may be used to perform.

In some embodiments, the gate spacer layer 30 are etched by a dry etch or a suitable etching process to form the source/drain recesses 40. In some embodiments, the dry etch process may implement an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. In some embodiments, the second regions R2 are recessed to expose sidewalls of the sacrificial layers 121 and the channel layers 122. In some embodiments, a thickness of the gate spacer layer 30 may be between 3 nm to 8 nm, but not limited to.

An inner spacer recesses 42 may be formed. The sacrificial layers 121 exposed in the source/drain recesses 40 are selectively and partially recessed to form inner spacer recesses 42 while the gate spacer layer 30 and the channel layers 122 are substantially unetched. In some embodiments, the channel layers 122 consist of Si and sacrificial layers 121 consist of SiGe, the selective recess of the sacrificial layers 121 may include a SiGe oxidation process followed by a SiGe oxide removal. In those embodiments, the SiGe oxidation process includes use of ozone. In some embodiments, the selective recess is a selective isotropic etching process (e.g., a selective dry etching process or a selective wet etching process), and the extent the sacrificial layers 121 are recessed is controlled by duration of the etching process. As shown in FIG. 4, the inner spacer recesses 42 extend inward from the source/drain recesses 40.

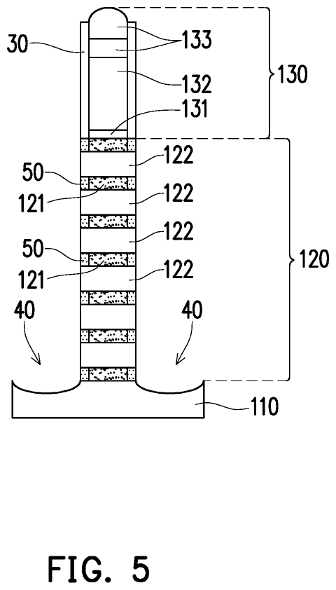

Referring to FIG. 5, an inner spacer features 50 may be formed in the inner spacer recesses 42. In some embodiments, an operation may include blanket deposition of an inner spacer material layer (not shown) over the substrate 110, and etch-back of the inner spacer material layer. In some implementations, the inner spacer material layer may be deposited using CVD, PECVD, LPCVD, ALD or other suitable method. The inner spacer features 50 may include metal oxides, silicon oxide, silicon oxycarbonitride, silicon nitride, silicon oxynitride, carbon-rich silicon carbonitride, or a low-k dielectric material. The metal oxides here may include aluminum oxide, zirconium oxide, tantalum oxide, yttrium oxide, titanium oxide, lanthanum oxide, or other suitable metal oxide.

The inner spacer material layer (not shown) is deposited into the inner spacer recesses 42 and over the sidewalls of the channel layers 122 exposed in the source/drain recesses 40, and the inner spacer material layer is then etched back to remove the inner spacer material layer from the sidewalls of the channel layers 122 to obtain the inner spacer features 50 in the inner spacer recesses 42. In some embodiments, the inner spacer material layer may be selectively removed without substantially etching the gate spacer layer 30. In some implementations, the etch back operations performed may include use of hydrogen fluoride (HF), fluorine gas (F 2), hydrogen (H 2), ammonia (NH 3), nitrogen trifluoride (NF 3), or other fluorine-based etchants. As shown in FIG. 5, each of the inner spacer features 50 may be in direct contact with the recessed sacrificial layers 121 and is disposed between two neighboring channel layers 122.

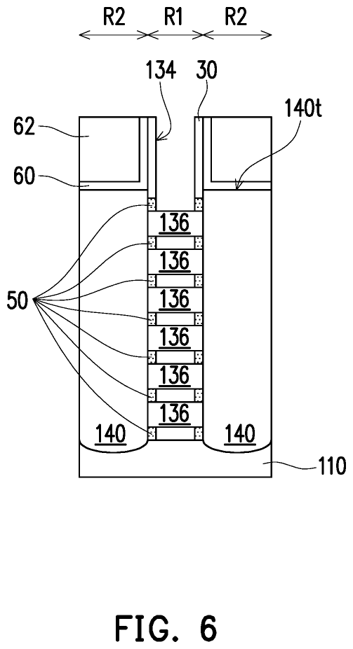

Referring to FIG. 6, source/drain features 140 may be formed on the second regions R2 by epitaxial processes. Suitable epitaxial processes include CVD deposition techniques (e.g., vapor-phase epitaxy (VPE) and/or ultra-high vacuum CVD (UHV-CVD)), molecular beam epitaxy (MBE), and/or other suitable processes. In some embodiments, the source/drain features 140 include silicon doped with a second n-type dopant different from the first n-type dopant. In some embodiments, the second n-type dopant is phosphorus (P) and the source/drain features 140 include silicon and phosphorus. In some alternative embodiments, the source/drain features 140 may be in contact with the inner spacer features 50 and the channel layers 122.

And then, a first etching stop material layer 60a may be formed conformally over the substrate 110, deposition of a first interlayer dielectric material layer 62a conformally over the first etching stop material layer 60a. In some examples, the first etching stop material layer 60a includes a silicon nitride layer, a silicon oxide layer, a silicon oxynitride layer, and/or other materials. The first etching stop material layer 60a is formed by ALD, plasma-enhanced chemical vapor deposition (PECVD) process and/or other suitable deposition or oxidation processes. The first interlayer dielectric material layer 62a is then deposited over the first etching stop material layer 60a. In some embodiments, the first interlayer dielectric material layer 62a includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The first interlayer dielectric material layer 62a is deposited by a PECVD process or other suitable deposition technique. As shown in FIG. 6, the first etching stop material layer 60a may be formed directly on top surfaces 140t of the source/drain features 140.

After the deposition of the first etching stop material layer 60a and the first interlayer dielectric material layer 62a, the structure may be planarized by a planarization process to expose the dummy gate electrode 132 (not shown). For example, the planarization process may include a chemical mechanical planarization (CMP) process. In some embodiments, the removal of the dummy gate electrode 132 and the dummy gate dielectric layer 131 results in gate trenches 134 over the first regions R1. The removal of the dummy gate electrode 132 and the dummy gate dielectric layer 131 may include one or more etching processes that are selective to the material in the dummy gate electrode 132 and the dummy gate dielectric layer 131. In some embodiments, the removal of the dummy gate electrode 132 and the dummy gate dielectric layer 131 are performed using as a selective wet etch, a selective dry etch, or a combination thereof that is selective to the dummy gate electrode 132 and the dummy gate dielectric layer 131. After the removal of the dummy gate electrode 132 and the dummy gate dielectric layer 131, surfaces of the first regions R1 are exposed in the gate trenches 134.

After the removal of the dummy gate electrode 132 and the dummy gate dielectric layer 131, the method may include operations to selectively remove the recessed sacrificial layers 121 between the channel layers 122 in the first region R1. The selective removal of the recessed sacrificial layers 121 releases the channel layers 122 to form channel members 136, wherein parallel channel members 122 spaced apart from one another and source/drain features 140 are disposed besides the channel members 122 and at opposite sides of the gate structure 135. The selective removal of the recessed sacrificial layers 121 may be implemented by selective dry etch, selective wet etch, or other selective etch processes. In some embodiments, the selective wet etching includes an APM etch (e.g., ammonia hydroxide-hydrogen peroxide-water mixture). In some embodiments, the selective removal includes SiGe oxidation followed by a SiGeOx removal. For example, the oxidation may be provided by ozone clean and then SiGeOx removed by an etchant such as NH₄OH.

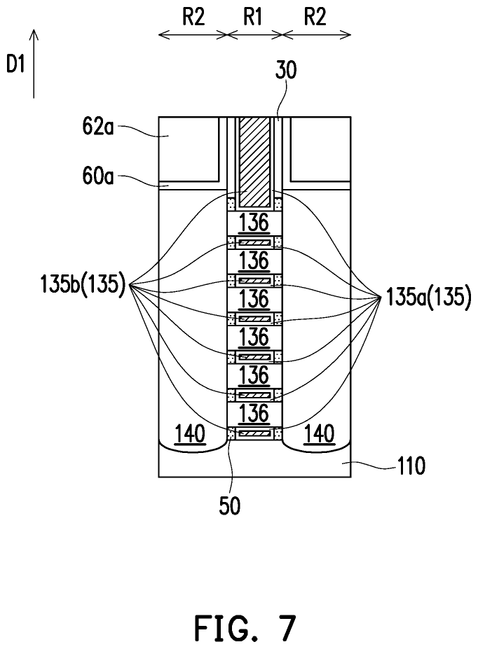

Referring to FIG. 7, the method may include further operations to form gate structures 135 to wrap around each of the released channel members 136 (formed by channel layers 122). The gate structures 135 may be a high-K metal gate structure. In some embodiments, the gate structures 135 are formed within the gate trenches 134 and into the space left behind by the removal of the sacrificial layers 121. In this regard, the gate structures 135 may wrap around each of the channel members 136. In various embodiments, each of the gate structures 135 includes a dielectric layer 135a and a gate electrode layer 135b formed over the dielectric layer 135a, the dielectric layer 135a includes an interfacial layer and a high-K gate dielectric layer formed over the interfacial layer. For example, High-K gate dielectrics, as used and described herein, include dielectric materials having a high dielectric constant, for example, greater than that of thermal silicon oxide. The gate electrode layer 135b used within the gate structure 135 may include a metal, metal alloy, or metal silicide, for example, the gate electrode layer 135b of the gate structure 135 includes Ti, Ag, Al, TiAlN, TaC, TaCN, TaSiN, Mn, Zr, TiN, TaN, Ru, Mo, Al, WN, Cu, W, Re, Ir, Co, Ni, other suitable metal materials or a combination thereof. In some embodiments, the dielectric layer 135a is formed by ALD, physical vapor deposition (PVD), CVD, oxidation, and/or other suitable methods, and the gate electrode layer 135b is formed by ALD, PVD, CVD, e-beam evaporation, or other suitable process. In some embodiments, a thickness of gate electrode layer 135b may be between 5 nm to 15 nm, but not limited to.

In various embodiments, a CMP process may be performed to remove excessive metal from the gate electrode layer 135b, and thereby provide a substantially planar top surface of the gate structure 135. The gate structure 135 includes portions that interpose between channel members 136 in the first regions R1. In here, a plurality of gate-all-around (GAA) transistors are formed on the substrate 110, and each of the GAA transistor may include the channel members 136 and the gate structure 135, wherein the channel members 136 are stacked along a direction D1 vertical to a top surface of the substrate 110, and the gate structure 135 is wrapping around the channel members 136. Further, the source/drain features 140 disposed on the substrate 110 and between the two GAA transistors. It should be note that, the aforementioned structure and process can also be applied to FinFET.

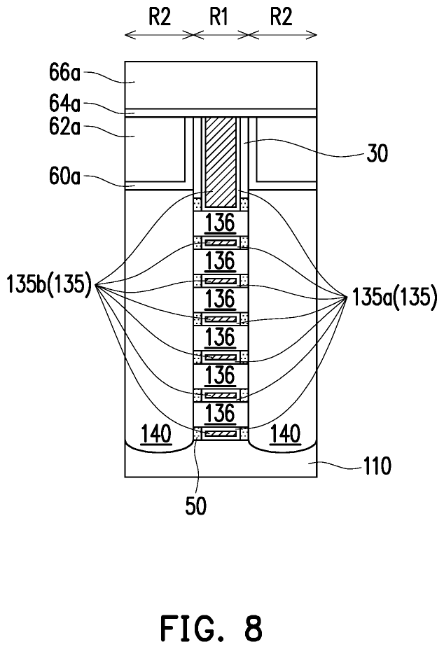

Referring to FIG. 8, after the CMP process to planarize the gate structures 135, the second etching stop material layer 64a is deposited over the planarized surface and the second interlayer dielectric material layer 66a is then deposited over the second etching stop material layer 64a. As the materials and formation processes of the second etching stop material layer 64a and the second interlayer dielectric material layer 66a may be similar to those of the first etching stop material layer 60a and the first interlayer dielectric material layer 62a, detailed descriptions of the second etching stop material layer 64a and the second interlayer dielectric material layer 66a are omitted for brevity.

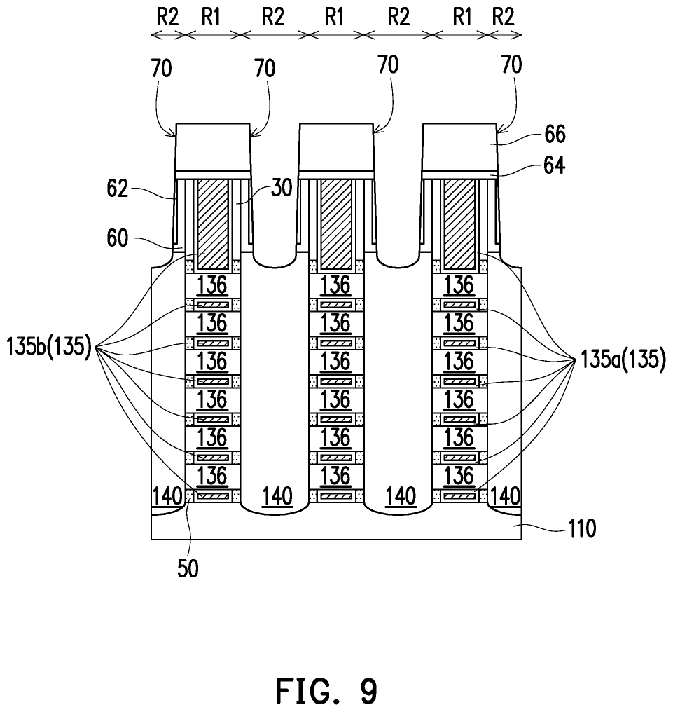

Referring to FIG. 9, source/drain contact openings 70 are formed penetrating through the first etching stop material layer 60a, the first interlayer dielectric material layer 62a, the second etching stop material layer 64a and the second interlayer dielectric material layer 66a to expose the source/drain features 140, wherein remained first etching stop material layer 60a refers to as first ESL 60, remained first interlayer dielectric material layer 62a refers to as first ILD 62, remained second etching stop material layer 64a refers to as second ESL 64, and remained second interlayer dielectric material layer 66a refers to as second ILD 66 as below. The contact opening etching process is performed to form the source/drain contact openings 70.

In some embodiments, during the etching process, the source/drain feature 140 have been recessed, and portions of the first ESL 60 and the first ILD layer 62 may be remained on a sidewall of the GAA transistor while exposed by the source/drain contact openings 70. In some embodiments, a thickness of the first ESL 60 ranges from about 2 nm to 8 nm and a thickness of the first ILD layer 62 ranges from about 3 nm to 5 nm, but not limited to.

In some embodiments, the etching process includes a dry etching process, a wet etching process, a RIE process, other suitable methods, or combinations thereof. A dry etching process may use chlorine-containing gases, fluorine-containing gases, and/or other etching gases. Wet etching solutions may include ammonium hydroxide (NH₄OH), hydrofluoric acid (HF) or diluted HF, deionized water, tetramethylammonium hydroxide (TMAH), and/or other suitable wet etching solutions. In some embodiments, the etching process includes multiple etching steps with different etching chemistries, designed for etching selectivity to form features having a desired profile.

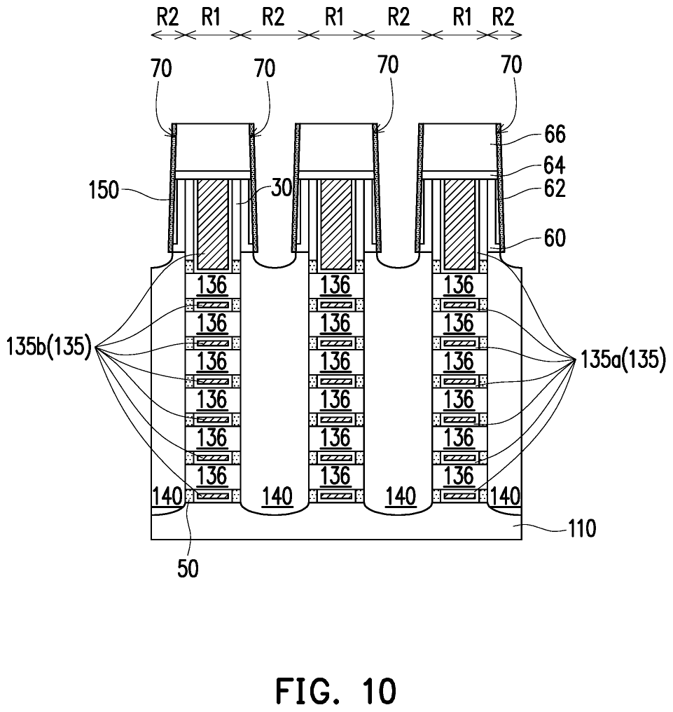

Referring to FIG. 10, a liner 150 may be deposited on the substrate 110. In some embodiments, the liner 150 is formed by conformally depositing a liner material (not shown) over the substrate 110, and then performing a breakthrough process to remove the liner material on a bottom of the source/drain contact opening 70 to form the liner 150. As seen in FIG. 10, the liner 150 is located on the sidewalls of the source/drain contact openings 70 without covering the bottom surfaces of the source/drain contact openings 70. In some embodiments, the liner material may include SiN, SiCN, SiOCN, SiON, or combinations thereof. In some embodiments, the breakthrough process can use any suitable etch process, such as a dry etch process. In some embodiments, for example, the breakthrough process may be a reactive ion etch (RIE) process with etch process gases including a form of fluorine. Additionally, any suitable additional process can be use. In some embodiments, a thickness of the liner 150 ranges from about 2 nm to about 5 nm, or, the thickness of the liner 150 ranges from about 1 nm to about 3 nm, but not limited to.

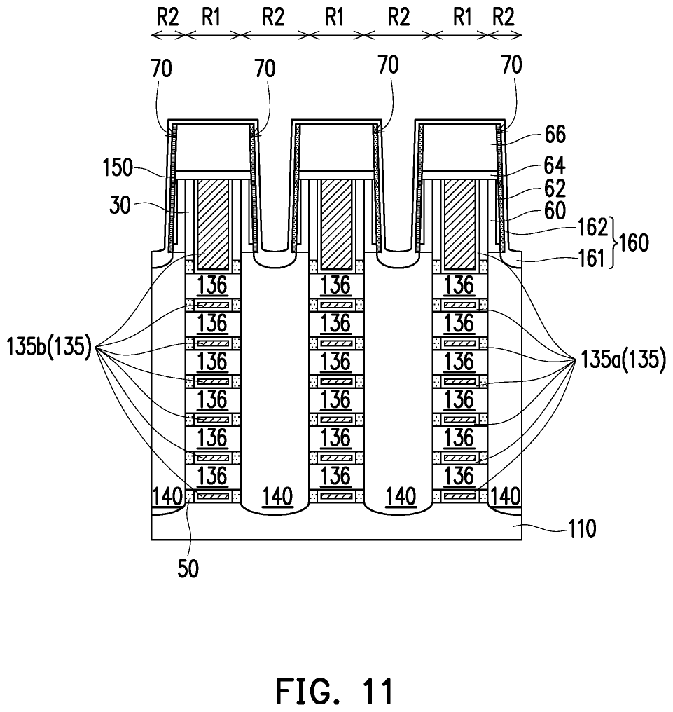

Referring to FIG. 11, a silicide layer 160 is deposited over the substrate 110. In some embodiments, the formation of the silicide layer 160 involves depositing a metal material (not shown) over the substrate 110 and performing a heating process to allow the metal to be reacted with the underlying silicon to form the silicide. In some embodiments, the metal material is deposited conformally over the substrate 110 and over the source/drain contact openings 70, conformally covering the profiles of the contact openings 70. That is, the metal material conformally covers the liner 150 as well as the exposed source/drain features 140. In some embodiments, the metal material includes cobalt (Co), titanium (Ti), nickel (Ni), molybdenum (Mo), ruthenium (Ru), or alloys thereof. In some embodiments, during the heating process, the metal from the metal material is reacted with underlying semiconductor material (e.g. silicon) of source/drain features 140 to form a first silicide portion 161 on the source/drain features 140 in the bottom of the source/drain contact openings 70, and the metal may be reacted with the material (e.g. silicon nitride) of the liner 150 to form a second silicide portion 162 on the liner 150. In some embodiments, as seen in FIG. 11, the first silicide portion 161 is in direct contact with the source/drain features 140, the second silicide portion 162 is in direct contact with the liner 150, and the first silicide portion 161 and the second silicide portion 162 are adjoining and contiguous, and both portions 161 and 162 are parts of the silicide layer 160.

In some embodiments, the material of the first silicide portion 161 may include a different composition from that of the material of the second silicide portion 162. Depending on the materials of the underlying features, when the material of the liner 150 includes SiN, the second silicide portion 162 may include more nitrogen within the silicide material (nitrogen-rich portion) compared with the first silicide portion 161. Similarly, the first silicide portion 161 may be a gradient silicide portion as the silicon content of the first silicide portion 161 keeps increasing when approaching the below source/drain features. In some embodiments, the material of the first silicide portion 161 includes NiSi, TiNiSi, CoSi, MoSi, RuSi, TiSi, or combinations thereof, and the material of the second silicide portion 162 includes NiSiN, TiNiSiN, CoSiN, MoSiN, RuSiN, TiSiN, or combinations thereof. In some embodiments, the compositions of the first and second silicide portions 161 and 162 are different, the first silicide portion 161 includes silicon-rich portion (Si-rich portion), and the second silicide portion 162 includes nitrogen-rich portion (N-rich portion). It should be note that the first silicide portion 161 and the second silicide portion 162 are formed through the same heating process, and there is no obvious interface between the first silicide portion 161 and the second silicide portion 162. In the following paragraphs, the first silicide portion 161 and the second silicide portion 162 may be referred to as silicide layers.

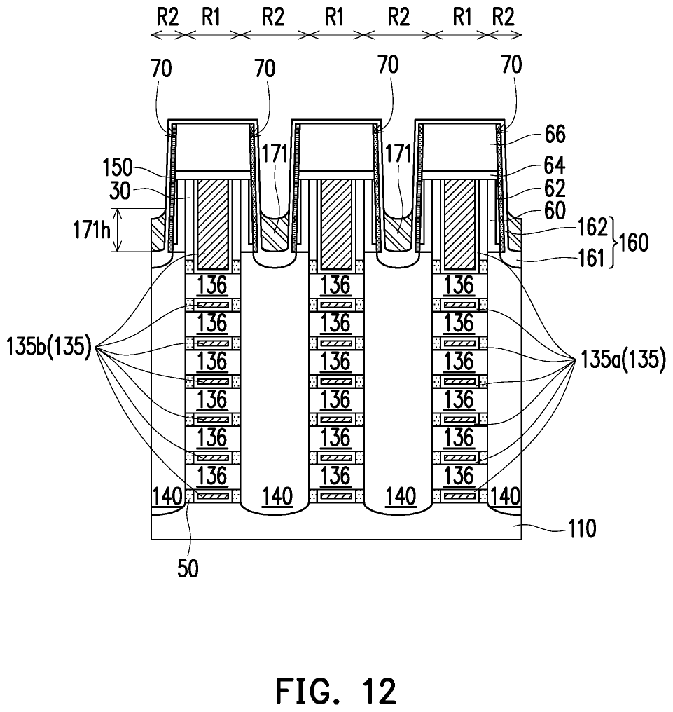

Referring to FIG. 12, first source/drain contacts 171 are formed on the silicide layer 160 in the source/drain contact openings 70. In some embodiments, the first source/drain contacts 171 are formed by conformally depositing a metal material (not shown) over the substrate 110 and filling into the contact openings 70, and the contact openings 70 are partially filled. Later, a metal etching back process is performed to remove on the metal material on the second ILD layer 66 and on the upper sidewalls of the contact openings 70 to form the first source/drain contacts 171. In some embodiments, the metal material includes Co, Mo, Cu, Ru, W, or combinations thereof, and formed by ALD, PVD, CVD, e-beam evaporation, plating or other suitable process. In some embodiments, the metal etching back process may include dry etching (e.g., RIE etching), wet etching, and/or other etching methods. In some embodiments, a height 171h of the first source/drain contact 171 ranges from 3 nm to 30 nm.

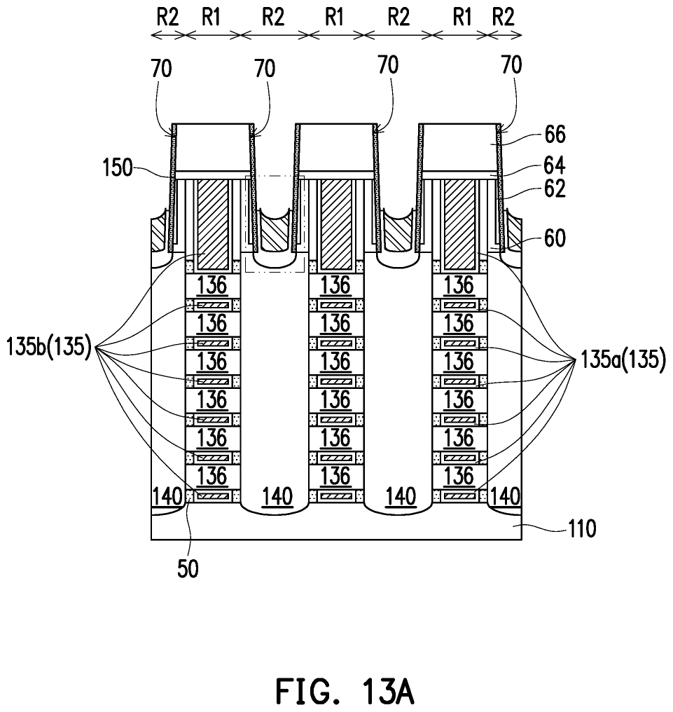

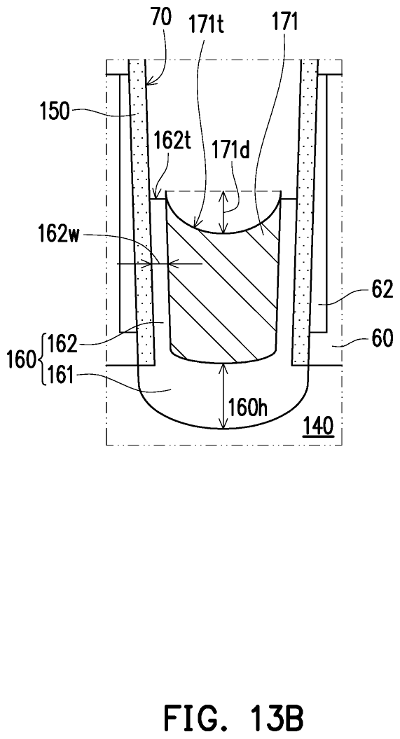

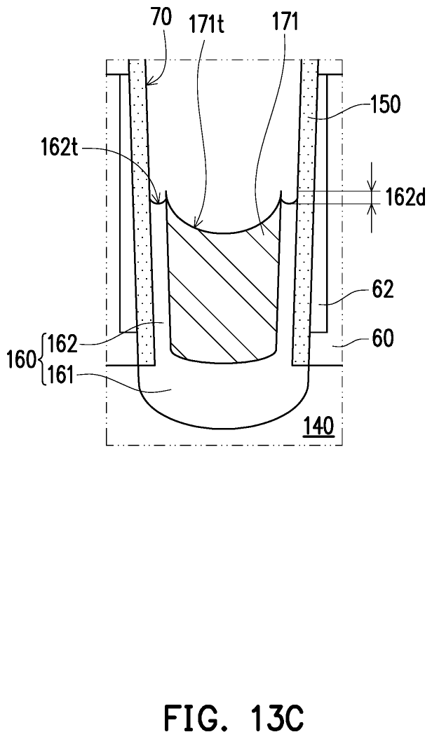

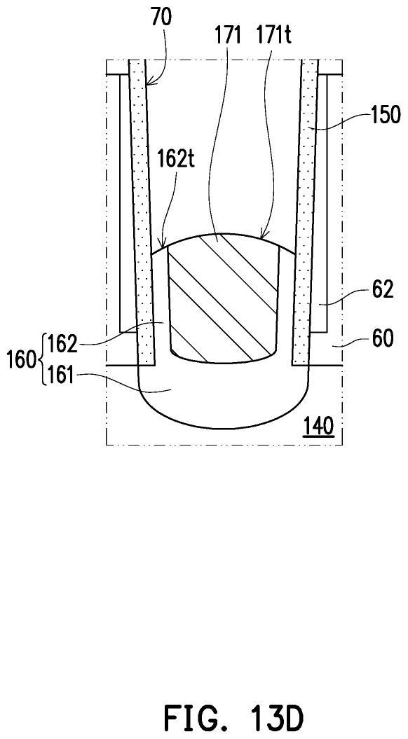

Following the process illustrated in FIG. 12, the process illustrated in FIG. 13A is performed. FIG. 13B is a schematic enlarged view of the dash line portion of the exemplary structure of FIG. 13A. FIG. 13C and FIG. 13D are schematic enlarged views of the alternative structures similar to the exemplary structure of FIG. 13B.

Referring to FIG. 13A, the second silicide layer 162 not covered by the first source/drain contact 171 is removed by performing an etching back process. In some embodiments, the etching back process is a pull-back process for partially removing the silicide layer 160. In some embodiments, the etching back process includes a dry etching process, a wet etching process, and/or a combination thereof. During the etching back process, the first source/drain contacts 171 are used as etching masks, the silicide layer 160 on the sidewalls of the openings 70 is removed such that the first silicide portion 161 and the second silicide portion 162 around and below the first source/drain contacts 171 are remained within the source/drain contact openings 70.

As shown in FIG. 13B, in some embodiments, a top surface 162t of the second silicide layer 162 is substantially flat (i.e. substantially a flat surface), and a top surface 171t of the first source/drain contact 171 is concave (bowl-shaped) with a dishing depth 171d (from the topmost of the first source/drain contact 171) ranging from 0.5 nm to 3 nm. That is, the ring-shaped second silicide layer 162 has the flat surface and the first source/drain contact 171 is dished. In some embodiments, as shown in FIG. 13B, a thickness of the second silicide layer 162 at sidewalls of liner 150 is between 0.5 nm to 10 nm, and a height 160h of the silicide layer 160 under the first source/drain contact 171 is between 0.5 nm to 10 nm.

In some embodiments, as shown in FIG. 13C, a top surface 162t of the second silicide layer 162 is slightly concave with a dishing depth 162d ranging from 0.5 nm to 3 nm of the second silicide layer 162, and a top surface 171t of the first source/drain contact 171 is also concave.

In some embodiments, depending on the tuning of the etching scheme, as shown in FIG. 13D, a top surface 162t of the second silicide layer 162 and a top surface 171t of the first source/drain contact 171 are adjoined and bulged to form a dome shape.

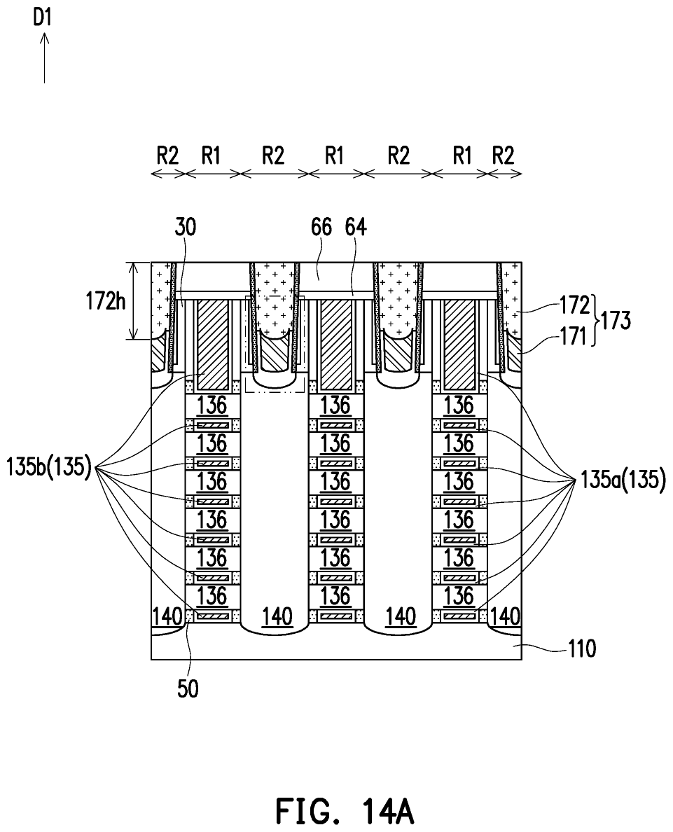

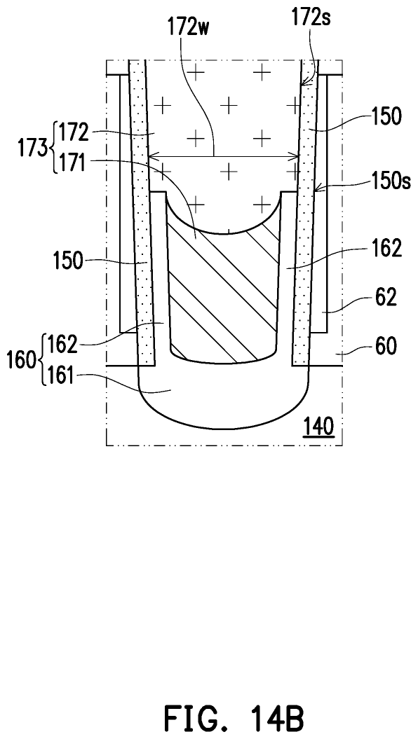

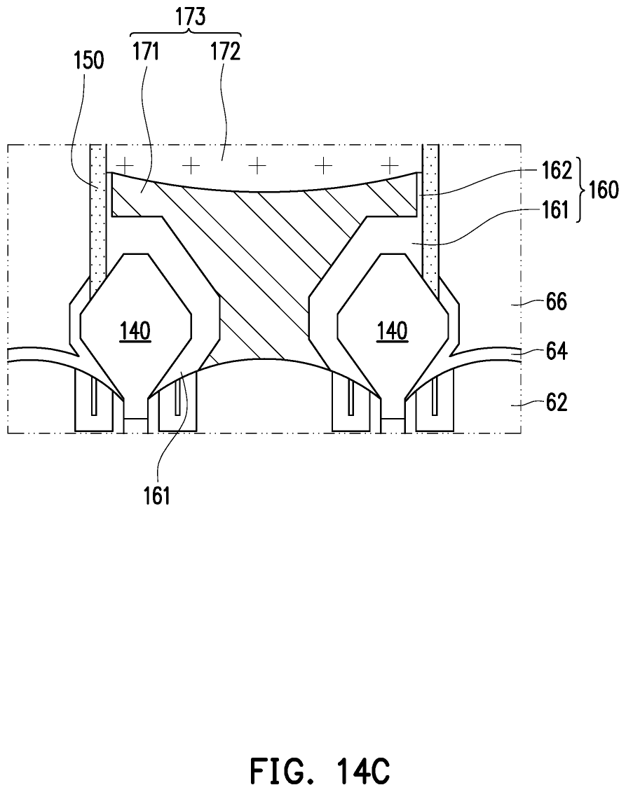

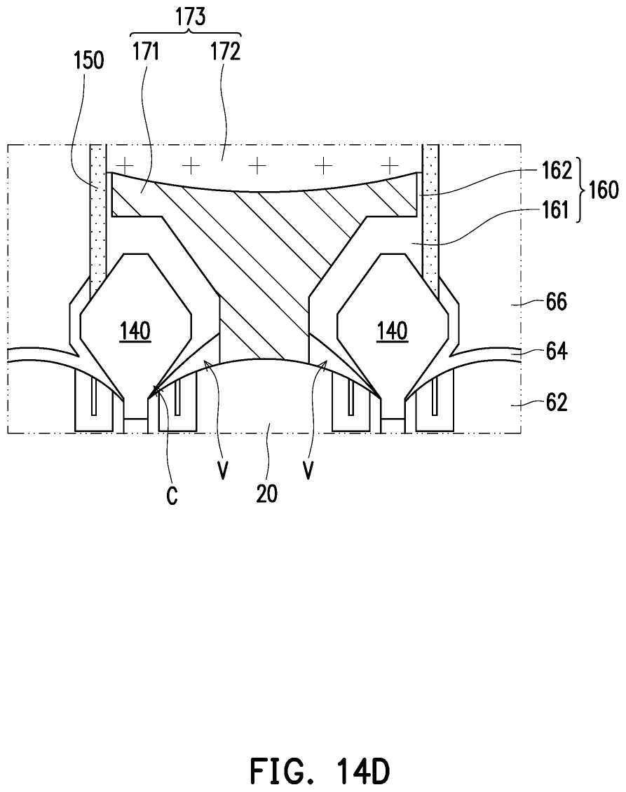

Following the process of FIG. 13A, the process illustrated in FIG. 14A is performed. FIG. 14B is a schematic enlarged view of the dash line portion of the exemplary structure of FIG. 14A. FIG. 14C is a schematic enlarged cross-sectional view of a portion of the structure of FIG. 14A along a cross-section orthogonal to the cross-section of FIG. 14B. FIG. 14D is a schematic enlarged cross-sectional view of exemplary structure similar to the structure of FIG. 14C.

Referring to FIG. 14A, in some embodiments, second source/drain contacts 172 are formed in the remaining space of the source/drain contact openings 70, and the first source/drain contact 171 and the second source/drain contact 172 together are referred to as source/drain contact 173. In some embodiments, the liner 150 is disposed around and surrounds the source/drain contact 173. In some embodiments, the metal material for forming the second source/drain contact 172 is deposited over the substrate 110, and then a CMP process is performed on the metal material to form the second source/drain contact 172 in a space surrounded by the liner 150 and the second silicide layer 162.

In some embodiments, referring to FIG. 14A and FIG. 14B, the recessed source/drain feature 140, the first silicide portion 161, the first source/drain contact 171, and the second source/drain contact 172 are stacked on the substrate 110 sequentially along the direction D1 (thickness direction), the second silicide portion 162 is disposed between the first silicide portion 161 and the second source/drain contact 172 of the source/drain contact 173, and the first source/drain contact 171 may be surrounded by the second silicide layer 162. Referring to FIG. 14B, the second silicide portion 162 extends on the sidewall 150s of the liner 150 in D1 direction. In some embodiments, due to the existence of the second silicide portion 162, the sidewalls of the first source/drain contact 171 are not aligned with (retreated from) the sidewalls of the second source/drain contact 172, and the width (diameter) of the first source/drain contact 171 is smaller than that of the second source/drain contact 172. That is, a width of a bottom surface of the source/drain contact 173 may be less than a width of a top surface of the source/drain contact 173. In some embodiments, the liner 150 may be extended along a sidewall of the second source/drain contact 172, and the liner 150 may be in direct contact with the sidewall of the second source/drain contact 172. In some embodiments, a width 172w of the second source/drain contact 172 ranges between 5 nm to 20 nm.

In some embodiments of the present disclosure, the second source/drain contact 172 is separated from the first silicide portion 161 by the first source/drain contact 171 and a portion of the source/drain contact 173 (the first source/drain contact 171) is in contact with and surrounded by the second silicide layer 162.

Herein, in some embodiments, the source/drain contacts are formed in two-staged, the lower source/drain contacts 171 are formed as the bases for seamless bottom-up metal contacts. Further, as the first source/drain contact 171 is formed before the formation of the second source/drain contact 172, the bottom silicide portion (the first silicide portion 161) is protected from the pulled-back process and remains damage free (or little damage), and the obtained source/drain contacts have better reliability and yields. In addition, using the source/drain contact 171 as the base to form the second source/drain contact 172 with a bottom-up metal filling process, no extra lining (e.g. TiN) or seed layer is needed, and the contact resistance is further reduced. In some embodiments, as the remained second silicide layer 162 is mainly located between the liner 150 and the first source/drain contact 171 without the residual silicide located on the upper sidewall of the liner 150, during the bottom-up growing process, the second source/drain contact 172 is formed with better selectivity and of good quality, so that the reliability and performance of the device are improved.

In some embodiments, metal material includes Co, Mo, Cu, Ru, W, or combinations thereof, and formed by ALD, PVD, CVD, e-beam evaporation, or other suitable process. In some embodiments, the material of the first source/drain contact 171 is different from the material of the second source/drain contact 172 and there is an interface between the first source/drain contact 171 and the second source/drain contact 172. In some embodiments, the material of the first source/drain contact 171 is the same as the material of the second source/drain contact 172 and there is no obviously interface between the first source/drain contact 171 and the second source/drain contact 172. In some embodiments, a height 172h of the second source/drain contact 172 may be between 3 nm to 50 nm.

In some embodiments, referring to FIG. 14A, the first ILD layer 62 is interposed between the liner 150 and the first ESL 60, and the first ESL 60 and the first ILD layer 62 are in direct contact with a sidewall 150s of the liner 150. In some embodiments, a lower portion of the sidewall 150s of the liner 150 is covered by the first ESL 60 and the first ILD layer 62, and an upper portion of the sidewall 150s of the liner 150 is covered by the second ESL 64 and the second ILD layer 66.

Referring to FIG. 14C, the first source/drain contact 171 is surrounded by the silicide layer 160, and the second source/drain contact 172 is surrounded by the liner 150. In some embodiments, the source/drain contact 173 overlies two source/drain features 140. In some embodiments, the liner 150 is in contact with the silicide layer 160 and the source/drain features 140.

Referring to FIG. 14D, in alternative embodiments, depending on the conformity or the reduced thickness of the first silicide portion 161, less metal material is filled in the bottom of the openings 70 and voids V are present at the corner(s) C of the source/drain feature 140. That is, voids V exist between the source/drain feature 140, the first ILD layer 62 and the first source/drain contact 171.

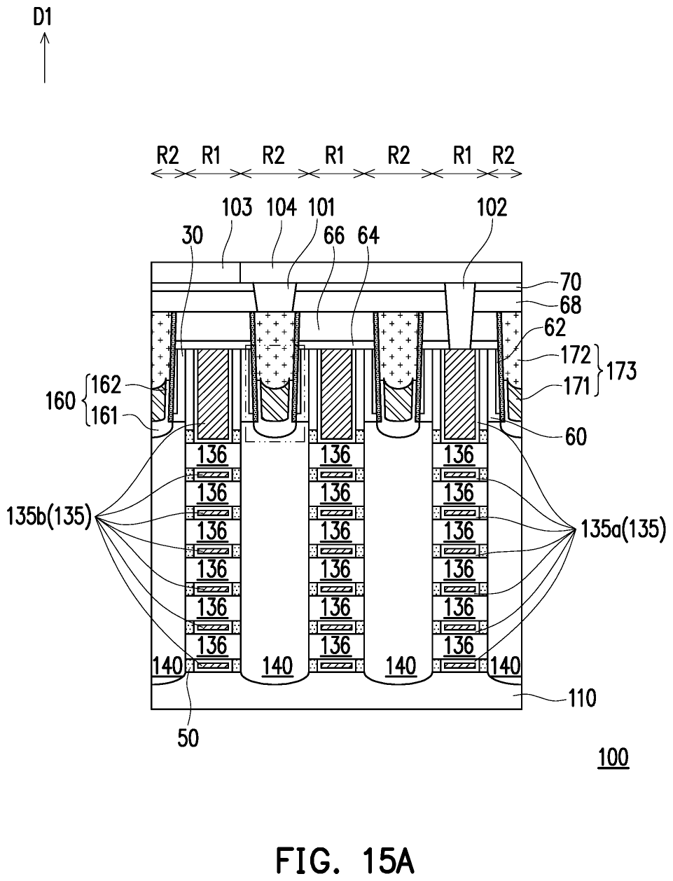

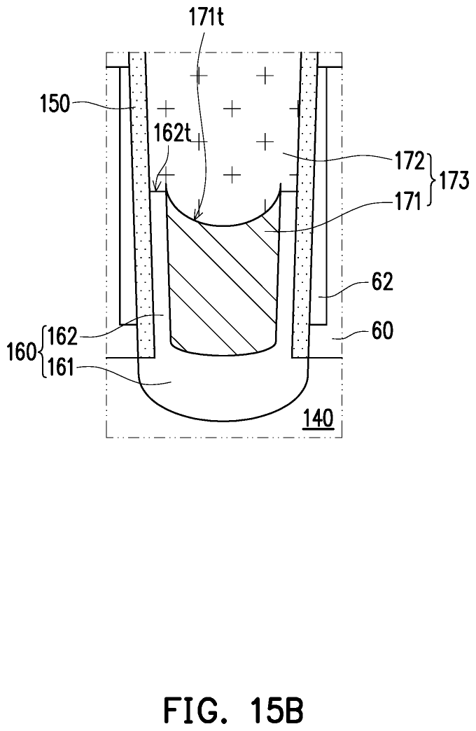

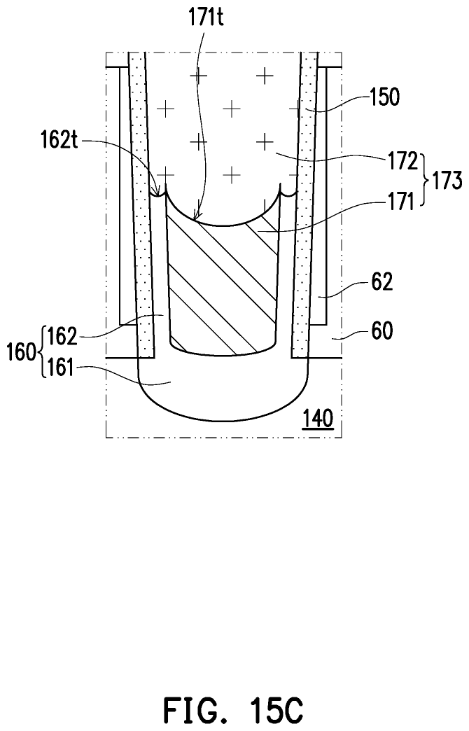

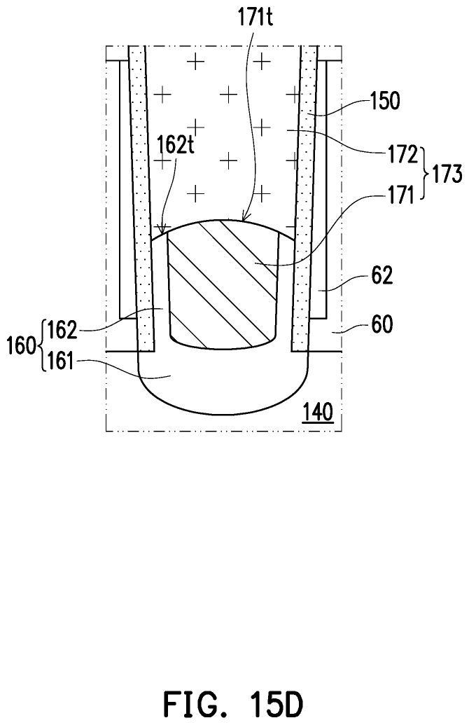

Following the process of FIG. 14A, the process illustrated in FIG. 15A is performed. FIG. 15B is a schematic enlarged view of the dash line portion of the structure of FIG. 15A. FIG. 15C and FIG. 15D are schematic enlarged views of exemplary structures similar to the structure of FIG. 15B.

Referring to FIG. 15A, after the source/drain contact 173 formation, the third ESL 68 is deposited over the planarized surface and the third ILD layer 70 is then deposited over the third ESL 68. As the compositions and formation processes of the third ESL 68 and the third ILD layer 70 may be similar to those of the first ESL 60 and the first ILD layer 62, detailed descriptions of the third ESL 68 and the third ILD layer 70 are omitted for brevity.

In some embodiments, source/drain vias 101 are formed on the source/drain contacts 173 and landed on a top surface of the second source/drain contacts 172. In some embodiments, gate vias 102 are formed on the gate structures 135 and landed on a top surface of the gate electrode layers 135b. And then, a hard mask 103 and an interconnection metal 104 may be formed on the third ESL 68 and the third ILD layer 70 to form semiconductor device 100. In some embodiments, the source/drain via 101 and the gate via 102 are electrically interconnected by interconnection metal 104. In some embodiments, the source/drain via 104 and the gate via 102 include Co, Mo, Cu, Ru, W, or combinations thereof and formed by ALD, PVD, CVD, or other suitable process. In some embodiments, interconnection metal 104 includes Cu and is formed by ALD, PVD, CVD, or other suitable process.

As shown in FIG. 15B, the second source/drain contacts 172 are formed and stacked on the top surface 162t (substantially flat) of the second silicide layer 162 and the concave top surface 171t of the first source/drain contact 171.

In alternative embodiments, as shown in FIG. 15C, the second source/drain contacts 172 are formed and stacked on the concave top surface 162t of the second silicide layer 162 and the concave top surface 171t of the first source/drain contact 171.

In some embodiments, as shown in FIG. 15D, the second source/drain contacts 172 are formed and stacked on the curved top surface 162t of the second silicide layer 162 and the protruded top surface 171t of the first source/drain contact 171 (both surfaces bulged as a dome shape). The bottom surface of the second source/drain contact 172 has a profile complementary to the profile of the top surfaces of the underneath second silicide layer 162 and the first source/drain contact 171. That is, the bottom surface of the second source/drain contact 172 is reverse bowl-shaped, as seen in FIG. 15D.

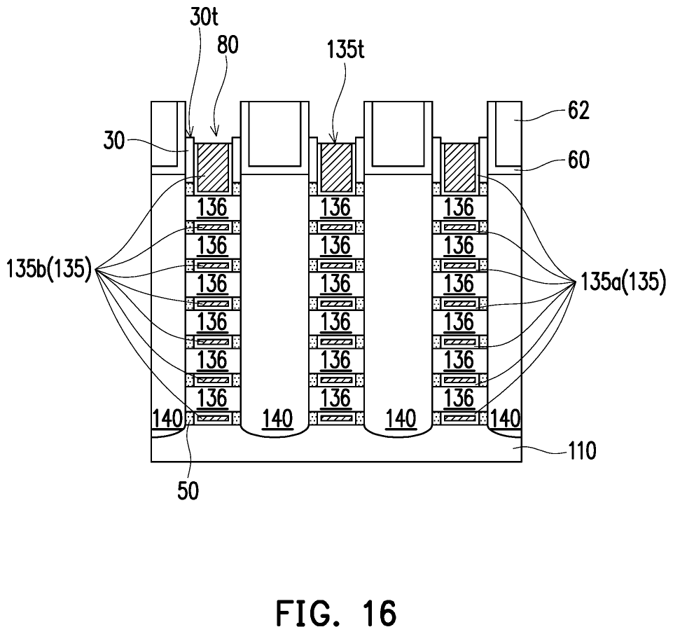

FIGS. 16-22 illustrate schematic cross-sectional views of a semiconductor device during a fabrication process, according to some embodiments of the present disclosure. Referring to FIG. 16, continue to FIG. 7, portion of the gate spacer layer 30 and the gate structure 135 are remove by etching back process, and after etching back process, a top surface 135t of remained gate structure 135 is lower than a top surface 30t of remained gate spacer layer 30, such that recesses 80 may be formed.

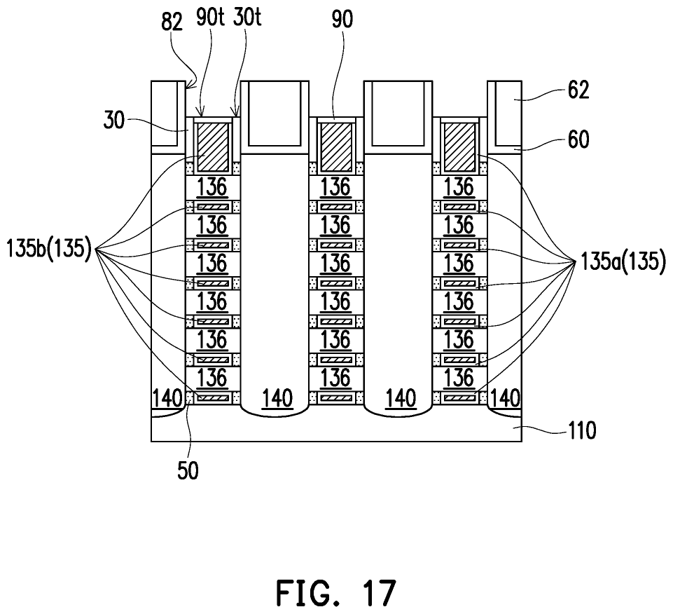

Referring to FIG. 17, a metal capping layer 90 may be formed in the recesses 80, and a top surface 90t of the metal capping layer 90 and the top surface 30t of the remained gate spacer layer 30 may be coplanar. In here, recesses 82 may be formed on the planar surface of the metal capping layer 90 and the remained gate spacer layer 30. In some embodiments, a material of metal capping layer 90 may include Co, W, Ru, Al, Mo, Ti, or combination thereof, and formed by ALD, PVD, CVD, e-beam evaporation, or other suitable process.

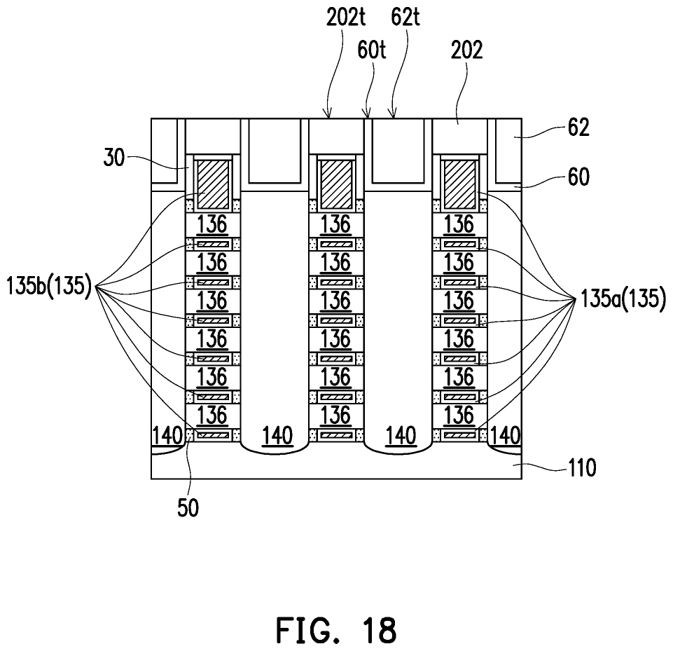

Referring to FIG. 18, a dielectric layer 202 is formed in the recesses 82, such that the dielectric layer 202 is formed on the GAA transistor, and a top surface 202t of the dielectric layer 202 and a top surface 60t of the first ESL 60 and a top surface 62t of the first ILD layer 62 may be coplanar. In some embodiments, a material of dielectric layer 202 includes SiN, SiOC, SiCN, SiOCN, ZrO₂, HfO₂ or combination thereof and is formed by ALD, plasma-enhanced chemical vapor deposition (PECVD) process and/or other suitable deposition processes.

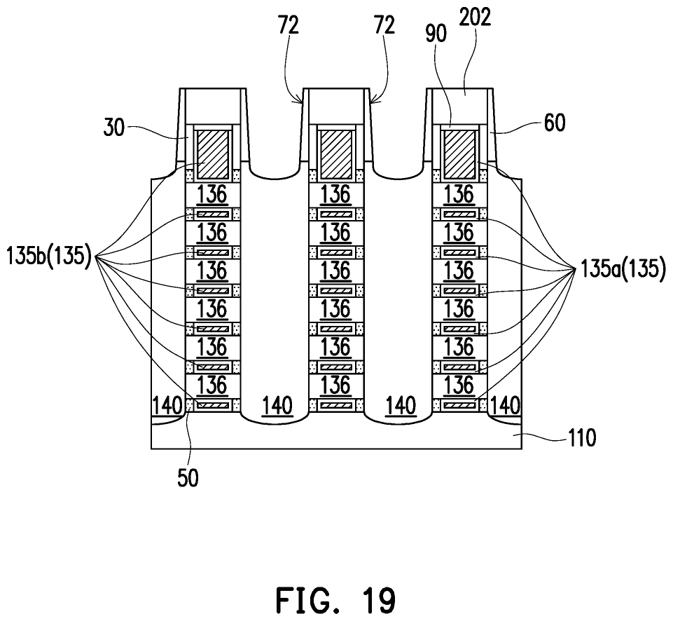

Referring to FIG. 19, an etching may be performed similar to FIG. 9, detailed descriptions of the etching is omitted for brevity. The difference between FIG. 9 and FIG. 19 is the first ILD layer 62 may be removed totally with the dielectric layer 202, such that there is substantially no first ILD layer 62 is remained in the source/drain contact opening 72 and remained first ESL 60 formed on the recessed source/drain feature 140 may be exposed by the source/drain contact opening 72.

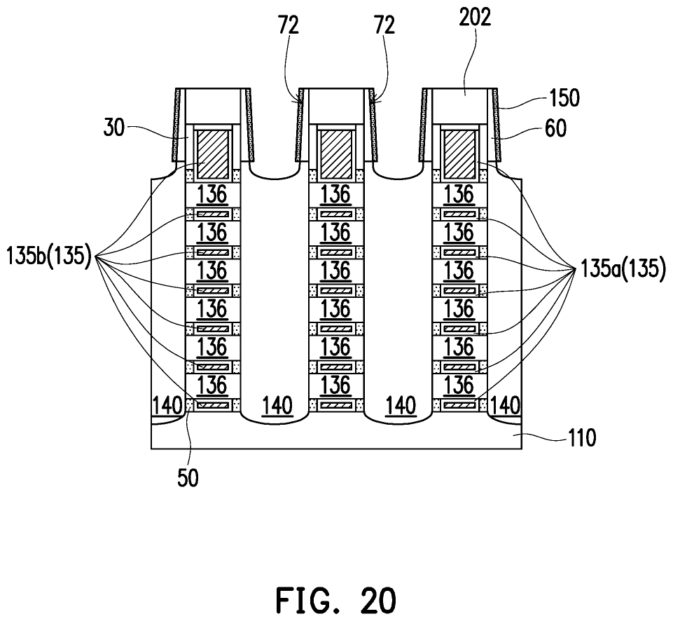

Referring to FIG. 20, the liners 150 may be formed in the source/drain contact opening 72 similar to FIG. 10, detailed descriptions of the liners 150 formation is omitted for brevity. The difference between FIG. 10 and FIG. 20 is the first ESL 60 may be extended from the recessed source/drain feature 140 to the dielectric layer 202 and the first ESL 60 may be in direct contact with the liner 150.

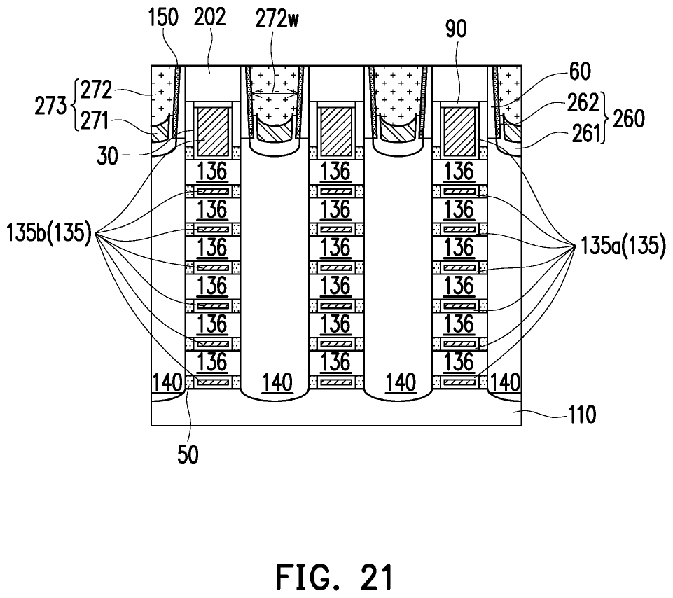

Referring to FIG. 21, a silicide layer 260, a source/drain contact 273 may be formed in the source/drain contact opening 72 similar to FIG. 11 to FIG. 14, detailed descriptions of the silicide layer 260 formation and the source/drain contact 273 formation are omitted for brevity. The difference between FIG. 21 and FIG. 14A is a size of a silicide layer 260 in FIG. 21 may be different from a size of a silicide layer 160 in FIG. 14, and a size of a source/drain contact 273 in FIG. 21 may be different from a size of a size of a source/drain contact 173 in FIG. 14. For example, a width 272w of the second source/drain contact 272 may be between 12 nm to 30 nm, but not limited to. The liner 150 may be located on sidewalls of the contact opening 72 and may be in contact with the etching stop layer 60.

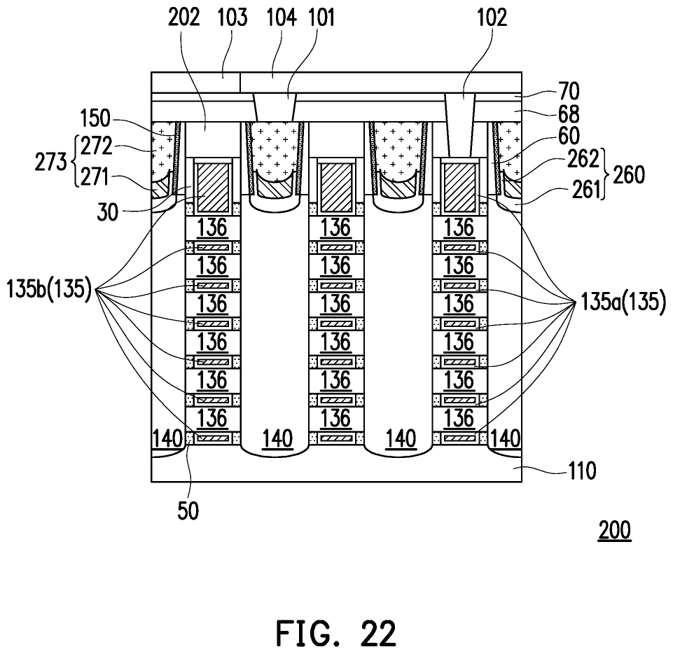

Referring to FIG. 22, the third ESL 68 and the third ILD layer 70, the source/drain vias 101, the gate vias 102, the hard mask 103, and the interconnection metal 104 may be formed similar to FIG. 15 to form semiconductor device 200, detailed descriptions of the third ESL 68 and the third ILD layer 70, the source/drain vias 101, the gate vias 102, the hard mask 103, and the interconnection metal 104 formation are omitted for brevity. The difference between FIG. 22 and FIG. 15 is the gate via 102 may be landed on a top surface of the metal capping layer 90, therefore, there is a better landing window with the metal capping layer 90. In here, GAA transistor including metal capping layer 90 may be formed.

In the present disclosure, the second source/drain contact 172 may be spaced from the first silicide portion 161 by the first source/drain contact 171 and portion of the source/drain contact 173 (such as the first source/drain contact 171) is embedded in the second silicide layer 162, therefore, seamless bottom-up metal is achieved, damage of bottom silicide (such as the first silicide portion 161) from the pulled-back process in FIG. 13A is reduced, and process window is enlarged to achieve better reliability/yield.

In accordance with some embodiments of the present disclosure, a semiconductor device includes parallel channel members spaced apart from one another; a gate structure wrapping around the channel members; source/drain features disposed besides the channel members and at opposite sides of the gate structure; a silicide layer disposed on and in direct contact with the source/drain features; and a source/drain contact disposed on the silicide layer, wherein the source/drain contact includes a first source/drain contact and a second source/drain contact stacked on the first source/drain contact, and the second source/drain contact is separate from the silicide layer by the first source/drain contact. In an embodiment, a material of the first source/drain contact is different from the second source/drain contact. In an embodiment, a material of the source/drain contact comprises Co, Mo, Cu, Ru, W, or combinations thereof. In an embodiment, the semiconductor device further includes a dielectric liner disposed around the source/drain contact. In an embodiment, the silicide layer includes a first silicide portion disposed on the dielectric liner and a second silicide portion disposed on the source/drain features. In an embodiment, the first source/drain contact is in contact with and surrounded by the silicide layer, and the second source/drain contact is in contact with the dielectric liner. In an embodiment, the first silicide portion has a composition different from that of the second silicide portion. In an embodiment, the semiconductor device further includes an interlayer dielectric (ILD) layer and an etching stop layer and a contact opening penetrating through the ILD layer and the etching stop layer, wherein the dielectric liner is located on sidewalls of the contact opening, and the ILD layer is interposed between the dielectric liner and the etching stop layer. In an embodiment, the semiconductor device further includes an interlayer dielectric (ILD) layer and an etching stop layer and a contact opening penetrating through the ILD layer and the etching stop layer, wherein the dielectric liner is located on sidewalls of the contact opening and is in contact with the etching stop layer.

In accordance with some embodiments of the present disclosure, a semiconductor device includes a substrate; channel members spaced apart and arranged in parallel to a top surface of the substrate; a gate structure wrapping around the channel members; source/drain features disposed on the substrate, beside the channel members and beside the gate structure; a first silicide layer disposed on and in direct contact with the source/drain features; a second silicide layer adjoined with the first silicide layer, wherein the first silicide layer has a composition different from that of the second silicide layer; a dielectric layer covering the source/drain features and the gate structure; a source/drain contact disposed in the dielectric layer and on the first and second silicide layers; and a liner disposed between the source/drain contact and the dielectric layer, wherein the second silicide layer is disposed on the liner. In an embodiment, a first portion of the source/drain contact is in contact with the liner, and a second portion of the source/drain contact is in contact with the first and second silicide layers. In an embodiment, a width of the first portion of the source/drain contact is larger than or about the same as a width of the second portion of the source/drain contact. In an embodiment, a material of the liner includes a nitride material, and the composition of the second silicide layer has a nitrogen content higher than that of the composition of the first silicide layer. In an embodiment, the second silicide layer is nitrogen-rich and the first silicide layer is silicon-rich. In an embodiment, a material of the source/drain contact comprises Co, Mo, Cu, Ru, W, or combinations thereof.

In accordance with some embodiments of the present disclosure, a manufacturing method of a semiconductor device includes forming separate and parallel channel members from a substrate; forming a gate structure wrapping around the channel members; forming source/drain features on the substrate and beside the channel members and at opposite sides of the gate structure; forming an interlayer dielectric (ILD) layer over the substrate covering the source/drain features; forming a source/drain contact opening penetrating the ILD layer to expose the source/drain features; forming a liner on a sidewall of the source/drain contact opening; forming a silicide layer over the liner and the exposed source/drain features; forming a first source/drain contact on the silicide layer inside the source/drain contact opening; and forming a second source/drain contact on the first source/drain contact inside the source/drain contact opening. In an embodiment, forming the silicide layer includes forming a first silicide layer on the exposed source/drain features and forming a second silicide layer on the liner. In an embodiment, forming a first source/drain contact on the silicide layer inside the source/drain contact opening includes: forming a metal material layer over the substrate and over the source/drain contact opening without filling up the source/drain contact opening; and performing an etching back process to partially remove the metal material layer to form the first source/drain contact inside the source/drain contact opening. In an embodiment, a manufacturing method of a semiconductor device further includes performing an etching process to partially remove the silicide layer after forming the first source/drain contact. In an embodiment, forming a second source/drain contact on the first source/drain contact inside the source/drain contact opening includes: forming another metal material layer over the substrate and filling up the source/drain contact opening; and performing a planarizing process to form the second source/drain contact.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
parallel channel members spaced apart from one another;
a gate structure wrapping around the channel members;
source/drain features disposed besides the channel members and at opposite sides of the gate structure;
a silicide layer disposed on and in direct contact with the source/drain features; and
a source/drain contact disposed on the silicide layer,
wherein the source/drain contact includes a first source/drain contact and a second source/drain contact stacked on the first source/drain contact, and the second source/drain contact is separate from the silicide layer by the first source/drain contact.

2. The semiconductor device as claimed in claim 1, wherein a material of the first source/drain contact is different from the second source/drain contact.

3. The semiconductor device as claimed in claim 1, wherein a material of the source/drain contact comprises Co, Mo, Cu, Ru, W, or combinations thereof.

4. The semiconductor device of claim 1, further comprising: a dielectric liner disposed around the source/drain contact.

5. The semiconductor device of claim 4, wherein the silicide layer includes a first silicide portion disposed on the dielectric liner and a second silicide portion disposed on the source/drain features.

6. The semiconductor device of claim 4, wherein the first source/drain contact is in contact with and surrounded by the silicide layer, and the second source/drain contact is in contact with the dielectric liner.

7. The semiconductor device of claim 5, wherein the first silicide portion has a composition different from that of the second silicide portion.

8. The semiconductor device of claim 4, further comprising an interlayer dielectric (ILD) layer and an etching stop layer and a contact opening penetrating through the ILD layer and the etching stop layer, wherein the dielectric liner is located on sidewalls of the contact opening, and the ILD layer is interposed between the dielectric liner and the etching stop layer.

9. The semiconductor device of claim 4, further comprising an interlayer dielectric (ILD) layer and an etching stop layer and a contact opening penetrating through the ILD layer and the etching stop layer, wherein the dielectric liner is located on sidewalls of the contact opening and is in contact with the etching stop layer.

10. A semiconductor device, comprising:
a substrate;
channel members spaced apart and arranged in parallel to a top surface of the substrate;
a gate structure wrapping around the channel members;
source/drain features disposed on the substrate, beside the channel members and beside the gate structure;
a first silicide layer disposed on and in direct contact with the source/drain features;
a second silicide layer adjoined with the first silicide layer, wherein the first silicide layer has a composition different from that of the second silicide layer;
a dielectric layer covering the source/drain features and the gate structure;
a source/drain contact disposed in the dielectric layer and on the first and second silicide layers; and
a liner disposed between the source/drain contact and the dielectric layer, wherein the second silicide layer is disposed on the liner.

11. The semiconductor device of claim 10, wherein a first portion of the source/drain contact is in contact with the liner, and a second portion of the source/drain contact is in contact with the first and second silicide layers.

12. The semiconductor device of claim 11, wherein a width of the first portion of the source/drain contact is larger than or about the same as a width of the second portion of the source/drain contact.

13. The semiconductor device of claim 10, wherein a material of the liner includes a nitride material, and the composition of the second silicide layer has a nitrogen content higher than that of the composition of the first silicide layer.

14. The semiconductor device of claim 13, wherein the second silicide layer is nitrogen-rich and the first silicide layer is silicon-rich.

15. The semiconductor device as claimed in claim 10, wherein a material of the source/drain contact comprises Co, Mo, Cu, Ru, W, or combinations thereof.

16. A manufacturing method of a semiconductor device, comprising:
forming separate and parallel channel members from a substrate;
forming a gate structure wrapping around the channel members;
forming source/drain features on the substrate and beside the channel members and at opposite sides of the gate structure;
forming an interlayer dielectric (ILD) layer over the substrate covering the source/drain features;
forming a source/drain contact opening penetrating the ILD layer to expose the source/drain features;
forming a liner on a sidewall of the source/drain contact opening;
forming a silicide layer over the liner and the exposed source/drain features;
forming a first source/drain contact on the silicide layer inside the source/drain contact opening; and
forming a second source/drain contact on the first source/drain contact inside the source/drain contact opening.

17. The method as claimed in claim 16, wherein forming the silicide layer includes forming a first silicide layer on the exposed source/drain features and forming a second silicide layer on the liner.

18. The method as claimed in claim 17, wherein forming a first source/drain contact on the silicide layer inside the source/drain contact opening includes:
forming a metal material layer over the substrate and over the source/drain contact opening without filling up the source/drain contact opening; and
performing an etching back process to partially remove the metal material layer to form the first source/drain contact inside the source/drain contact opening.

19. The method as claimed in claim 18, further comprising performing an etching process to partially remove the silicide layer after forming the first source/drain contact.

20. The method as claimed in claim 19, wherein forming a second source/drain contact on the first source/drain contact inside the source/drain contact opening includes:
forming another metal material layer over the substrate and filling up the source/drain contact opening; and
performing a planarizing process to form the source/drain second contact.
